(19) United States
(12) Patent Application Publication
(10) Pub. No.: US 2011/0309330 A1
(43) Pub. Date: Dec. 22, 2011

(54) 2-dimensional quantum wire array field effect transistor/power-transistor/switch/photo-cell

(76) Inventor: Frank M. Ohnesorge, Gilching (DE)

(21) Appl. No.: 12/379,834

(22) Filed: Mar. 3, 2009

(30) Foreign Application Priority Data
Mar. 10, 2008 (DE) DE102008015118.1

(51) Int. Cl. H01L 29/775; H01L 31/0352

(52) U.S. Cl. 257/20; 136/255; 257/E29.245; 257/E31.033

(57) ABSTRACT

One, groups of several or many parallel vertical quantum wires arranged as 2-dimensional array interconnecting the source and drain of a transistor, are modulated with respect to their quantum-mechanical conductivity via the strength of an applied field.

The Ohmic resistance of the source-drain connection via the quantum wire array is in the conducting state practically zero and the quantum wire field effect transistor's response time is solely determined by the switching time of the gate-field, which can be magnetic, electric, electroacoustic or optical.

Applications for large arrays (>10¹⁰ parallel QWs) is a power transistor, for small arrays (single or few parallel QWs) it is non-volatile information-storage e.g. mediated via ferromagnetic/ferroelectric layers and/or nanoparticles, where due to the properties of 1-dimensional quantized conductivity multi-level logic is realized. Through optical gating of this transistor, an extremely highly resolving 2-dimensional array of photodetectors is possible, thus forming a camera and even a solar cell.

### SUMMARY

One, several or very many parallel quantum wires (e.g. especially 1-dimensional quantum-conducting heavy ion tracks—“true” quantum wires at room temperature—see EP1096569A1 [1] and [2], or also perhaps SWCNTs, vertically directed or also slightly tilted—up to about 30 degrees—arranged in a 2 dimensional plane, which as a 2-dimensional array interconnect the source and drain contacts of the here invented transistor, are modulated with respect to their quantum-mechanical conductivity via the strength of an applied magnetic field, which is variable or homogenous in space locally across the 2 dimensional quantum wire array [3].

The switching time of the transistor is determined practically solely by the switching time of the magnetic field (time constant of the “magnetic gate”), the Ohmic resistance of the source drain connection via the quantum wire array is in the conducting state practically zero. The controlling “Gate”-magnetic field having a component normal to the quantum wires can be generated by a small controlling current through some inductance (manifestation example/embodiment 1, FIG. 6) or also by a suitable (locally variable) direction of the magnetization in a ferromagnetic thin film/layer (e.g. Fe, Co, Ni)—manifestation example/embodiment 2, FIG. 7—, or also for example in a thin film/layer comprised of/consisting of metallic (ferromagnetic) nanoparticles (e.g. Fe, Co, Ni) or also “current-less” through an electrostatically charged tip (embodiment 3a analogous to FIG. 6) or via a suitable polarization of a ferroelectric thin film/layer or liquid crystals/nanoparticles in an electric field—embodiment 3b, as in FIG. 7. The quantum wire transistor can also be switched/controlled optically.

Applications in the case of very large arrays (>10¹⁰ parallel QWs) would be a power transistor, in the case of very small arrays (single or a few parallel QWs) it would be non-volatile information storage, where due to the particular properties of 1-dimensional quantized conductivity a multi-level logic can be realized. In the case of optical switching/controlling of the quantum wire transistor, an extremely highly resolving 2-dimensional array of photodetectors is thinkable/imaginable/envisionable, where in that case the single QWs would have to be electrically connected one by one, which in turn is supposedly determining the limit of the achievable area density of the pixels.

The 1-dimensionally quantized electrical conductivity of the quantum wires here is indeed characterized in that, that the source-drain-current-voltage (I_{sd} plotted versus U_{sd}) at room temperature

Firstly (see FIG. 2) is a staircase characteristic (with steps/almost plateaus on an 0.2-0.5 Volts scale on the U_{sd}-axis) with at higher voltages occurring negative differential resistance (caused by Esaki-tunnelling of “hot electrons”), and that

Secondly (see FIG. 4) especially in an U_{sd}-range in the vicinity around 0 Volts, i.e. especially in the first Coulomb suppression level extremely sharp current (I_{sd}) peaks are occurring, caused by (quantum) peaks in the 1-dimensional conductance at source-drain voltages U_{sd} with a separation in voltage of about 2 mVolts. Needle-like current peaks (I_{sd}) of a height up to 1 nAmpere were observed significantly below source drain voltages of 50-200 mVolts.

In particular, it is hereby emphasized, that the characteristic curves I_{sd} versus U_{sd} are measured and plotted, not—as usually—I_{sd} versus a gate voltage or a gate field strength respectively (e.g. B-field) was displayed/plotted. In the usual case of I_{sd} versus gate field a staircase characteristic is resulting due to sole charge quantization (Coulomb blockade), in the case of I_{sd} versus U_{sd} a staircase characteristic is resulting, but/and especially the quantized conductance peaks are resulting not until actual 1-dimensional ballistic conductivity—i.e. a tunnelling of the conducting electrons through the 1-dimensional quantum states just like in a wave guide—is in effect, and the lateral extension of the quantum wire is of the size order of the Fermi-wavelength (O(a few Angströms to 1 nanometer) of the electrons, and not just the mean free path or phase coherence length (with respect to the diffusive scattering of the electron at atoms, other electrons, phonons), which are much larger. The theory about this is treated e.g. in [4].

Especially if source and drain electrodes—which can be micro-structured—also show ballistic conductivity (see e.g. [5], for the case of Tu and Mo at very low temperatures), here perhaps if e.g. they would be consisting of crystalline Cu or Au already at moderately low temperatures or if they would be a superconductor/superconducting at low temperatures or even would consist of a 2-dimensional electron gas—2-DEG—at room temperature and the 2-dimensional nanowire array would consist of very well identical quantum wires (geometry, material)—embodiment 5, FIG. 11—then phase-dependent (wave function of the ballistic electrons) effects in the quantum wires would enhance the sensitivity (i.e. the gain) of the transistor function significantly, since for instance an applied (inhomogeneous) B-field (-component) vertical to the quantum wires would instantaneously induce various phase shifts of the wave functions (free electron in the 1-dimensional electron gas, or an electron which is transmitted through a 1-dimensional quantum state, i.e. is tunnelling into and out of that quantum state) in all those many quantum wires and the resulting total summed up (summed “interferometrically”) current through all the wires (the entity of the wires) would be drastically reduced—in complete analogy to a quantum interference device, e.g. as a SQUID. This effect would occur already, even though weaker, if the electrodes are not ideal metals nor even 2-DEGs/superconductor, at room temperature. A 2-DEG as source and drain electrode would of course also function at room temperature which would be the ideal case.

The current through quantum wires can also be modulated optically (embodiment 4, FIG. 9) by roughly infrared light, since then excitations between quantum states in the quantum wires can occur. (z.B. [6]). It showed experimentally, that using the present invention set-up even current as in a solar cell can be generated (FIG. 10, current flow of several 0.1 nAmpere at voltages of 0 Volts through a single quantum wire under illumination, while the exact power contribution of that single quantum wire could not yet evaluated because of the other two simultaneously illuminated and even in large area illuminated hetero junctions of the experimental set-up, which alone neither are showing a pronounced plateau nor a non-zero current I_{sd} at U_{sd}=0 in the I_{sd}-Uₛₑcharacteristics—as the one visible in FIG. 5—and without the quantum wire are delivering a current higher by a factor of 1000 at the same voltage modulation/cycling—i.e. delivers a I_{sd}−U_{sd} characteristics a factor of 1000 steeper without any plateaus. At a counter voltage of about 0.2 Volts, the current (under illumination) is suppressed to zero, which leads to an estimated (total) power of the single quantum wire photo cell of 0.02 nWatts.

If the QWs in the 2-dim array are electrically contacted one by one, i.e. if they can be “read out” one by one, because of the photo sensitivity of the QWs a extremely highly resolution-capable photodetector array can be realized (more than one pixel per (100 nm)²). This electrical contact could be realized via a resistor cascade reminiscent of a shift register or a regular CCD-array—modern (and also elaborate) lithography methods allow such small structure sizes. At such high area density of the pixels (up to about 10¹² per cm² would be feasible), it can be spoken of a artificial retina.

The primary, and most simply realizable embodiment of the here invented mesoscopic quantum-electronic component is a power transistor, in which the current through each of these approximately 10¹⁰ parallel QWs/cm² is modulated or switched via a magnetic field, where the I_{sd}-U_{sd} characteristic resulting from the sum of all currents through the many single QWs of such a magnetic field effect power transistor can be tailored through adjustment of the spatial variation of this magnetic field across the 2 dimensional array of QWs. This can be realized for instance by a strong and variable B-field gradient emanating from a tip-shaped soft-iron-core (adjustable inhomogeneous B-field) or by a ferromagnetic film—e.g. deposited on the source electrode—whose magnetization can be “written” laterally (spatially) variable which in turn stores this [spatially defined inhomogeneous] magnetization in a non-volatile manner, even after the electro-magnetic (“writing”) tip has been removed. At a current of about 1 nAmpere per QW (at about 1 Volt applied source-drain-voltage U_{sd}) a total controlled current of 10 Amperes per cm² component surface area is basically possible. The total source drain current I_{sd} can also be modulated optically (see above), similarly applicable like a photo-thyristor.

If all the parallel QWs are electrically contacted in small groups (only a few parallel or even single QWs), via the above mentioned “writing” magnetization a computer mass storage device can be realized—see patent claim 8.

One manufacturing method of such an array of very many parallel QWs, vertically embedded in an insulating film (e.g. DLC, SiC, polymers) for use in such an here invented power transistor is extensively described in [1], where the achievable maximum [area] density of such vertical parallel QWs while still being sufficiently electronically insulated from each other, is roughly 10¹¹ wires/cm². Since the particle tracks (heavy ion tracks) show clear electronic quantization effects at room temperature (staircase I-V-curve, quantum conductance peaks, along the QWs), which means that they are room temperature QWs, and eventually since all that it is supposed/suggested that the directed/oriented impact of single high energy ions (i.e. extremely high energy density) generates single SWCNTs by extremely local graphitization of the DLC material; this is because such staircase I-V-curves or even quantum conductance peaks (if these at all) in the source-drain I_{sd}-U_{sd}-curve along the QW (meaning not just steps in the conductance I_{sd} as a function of a gate voltage) as in FIG. 2 and especially in FIG. 4 (at room temperature) are seen at room temperature in quasi 1-DEGs not until down to lateral size of 1-2 nm. Conductance peaks reminiscent of the ones seen here in the Coulomb suppression plateau, however, as a function of U_{gate} (and not of U_{sd} like here) are observed in [7] at extremely low temperatures (100 mK) in QDs (and not in 1-dimensional QWs as here); analogies of the fundamentally underlying theoretical physics (single electron transmission through quantum states, in the references [7,8]) to the here observed effects are still unclear to me, also the theoretical research in [8] describes QDs, not QWs and also only conductance peaks as a function of the gate voltage. In the case of CNTs it is never possible to consider U_{sd} and U_{source-gate} completely independent from each other.

As a substrate for the DLC-film in which the QWs are produced by the impact and passage-through with (many) single high energy heavy ions, besides highly doped electrically conductive single crystal semiconductor wafers (in the case of Si-wafer atomically flat) as in [1] also other materials, which are flat on a nm-scale and electrically very well conducting, can be used as a substrate, for instance crystalline metal films (e.g. Au, Pt, Pa, Cu), for instance deposited on mica as a solid, atomically flat support. Ideal would be using a highly doped semiconductor, which would instantaneously form a 2-DEG at the hetero junction with the insulating DLC-film. The same obviously holds/applies for the cover electrode at the upper end of the vertical QWs-array, which however has to be very thin, so that gate field effects can reach all the ways down to the embedded QWs, or respectively has to be transparent for optical current modulation of the current through the QWs.

In [1] the lengths of the, in an insulating film embedded QWs lay in the range of about 100 nm—there determined by the film thickness of the insulating, the wires embedding matrix.

The range of swift heavy ions in the film material is much higher (about 1-5 nm/(keV/nucleon)). The maximum, with realistic effort reachable ion track length in the there used layer matrix (e.g. electrically insulating DLC, perhaps also crystalline SiC) would be about 30 μm at about 11 MeV/nucleon particle energy. At a voltage rejection of about 150V/μm in DLC [9] a maximum upper limit of the break through voltage of the here invented power transistor would be about 5 kV, of course limited then further by the voltage durability of the QWs themselves, since because of theoretically R≈0 in turn by their current durability, where so far up to about 10 nA per QW (at very few volts) the typical known quantization effects (staircase-I-V-curve) were just still visible [1]. That would in turn mean, that about 1 kA at about a few Volts, i.e. about 1 kWatt maximum controlled power per cm² component area can be reached at ≈10¹¹ QWs/cm².

Another extremely interesting manufacturing method for such a large 2 dimensional array of vertical wires with diameters in the nanometer range (typically 20-50 nm) an area density of also roughly 1 wire per (100 nm)² is claimed presented in [10], while there the grown nanowires are however significantly bigger in diameter as compared to in [1], it is however also mentioned [in [10]] that 1-2 nm diameters are possible in principle. Although the nanowires in FIG. 7 of reference [10] exhibit—and only at extremely low temperatures (4.2K) however—yet a strongly non-linear I-V-curve showing a broad plateau around 0 Volts, which suggests an influence of Coulomb-blockade effects, but does not demonstrate by far a quantum wire with 1-dimensional ballistic conductivity and staircase characteristics/conductance peaks. SWCNTs are however generally accepted as “true” QWs, but those are much thinner, very few nm in diameter (only or even smaller), while there in the measurement in [10] surely the still much wider MWCNTs are present—it is obviously only claimed there in [10] a “vertical nano size transistor using CNTs and manufacturing method thereof” and not a QW-array-FET at room temperature, as claimed here for the present invention, not to even mention a 2-dimensional large array of billions of “true” QWs as here in the present invention.

One further extremely interesting manufacturing method of extremely thin (0.4 nm) metallic crystalline nanowires is described in [11]. The electrical characterization of single such wires is to best of my knowledge still lacking, the electrically contacting such wire is certainly very difficult.

The here invented transistor would already function at room temperature. Through the B-field dependent phase effects of the electronic wave function it would function significantly more sensitively, if 2 DEGs could be realized as source and drain electrodes, even this at room temperature. Then the entity consisting of the 2-dimensional array of parallel (upright standing) QWs and of the ideal metal electrodes/2-DEGs would be a quantum interference device (QUID), which in a wider sense could be regarded as a model system for the understanding of a 1-dimensional (meaning 1-directional) pseudo superconductor at more or less room temperature (i.e. a 1-dimensional, meaning 1-directional, ideal electric conductor, exhibiting a resulting phase of the superimposed wave functions, B-field normal to the QWs could perhaps be expelled from the QW-array upon turning up/switching on the B-field—because of the phase shifts of the single wave functions with respect to each other in the single QWs short-cut into loops (QUIDs) (see [1])—for which the Aharonov-Bohm effect is taking care of, even though if there were no B-field within the wires themselves at all), while a possible expelling of B-fields within the wires would still have to be clarified [14].

A 1 cm² solar cell of this here invented design, in which through illumination by light (roughly 633 nm) of about 0.5 mW focussed on roughly a spot of 30 μm (where crudely estimated only <1% actually reaches the QW-array surface, since opaqued by the measuring AFM-/STM-probe tip) in a single QW a current of order 0.1 nA is generated, which at a counter voltage of about 0.2 Volts is compensated back to zero, would at 10¹⁰ parallel QWs per cm² and at equivalently (1 cm²/(30 μm)²)×0.5 mW×0.01=0.5 W optical power deliver a current of 1 A at a DC-power of 0.2 W. That would be roughly an efficiency of 40%. Hereby, it is unclear, as already mentioned above, how large the influence of other possible light sensitive junctions in the set-up really is: Highly doped Si-substrate—graphitic QWs—semiconducting probe tip (highly boron doped diamond).

On its illuminated upper side, the 2-dimensional array of parallel QWs could be interconnected by means of electrically conducting ITO-glass, or for enhancing the efficiency by crystalline and very thin and thus almost transparent metal films. On its lower side the QW-array is connected/interconnected as in [1] by means of a highly doped, electrically conducting semiconductor single crystal or another extremely flat well conductive substrate, ideally forming a 2-DEG with the DLC layer.

### “The Problem”

In power electronics mainly 2 problems exist: Power losses through generation of heat and controlling currents as well as long switching times constants/[relaying times/time constants]. Quantum electronics can solve these two problems, because ballistic electronic conductivity (in the large load current) is running in a quantum transistor/switch without Ohmic resistive losses (R=0 theoretically) as well as the instantaneous, extremely sensitive control/switching signal itself of the quantum electronic element by a field occurs loss-less and practically instantaneous. Controlling the “gate” itself of a quantum transistor has to be mediated by an electromagnetic field (magnetic, electric, optical, or even electro-acoustical) and solely the generation of this small controlling field determine power loss and time constant of this transistor/switch ideally. In addition in such a quantum mechanical/electronic transistor/switch/relay do not exist any mechanical contacts (as in a mechanical relay) between gate and the quantum mechanical source-drain element.

In information storage technology so far only a 1 bit logic is available for the single memory cells (current on or off upon read out of GMR-harddiscs or respectively capacitor charged or not in DRAMs or Flash-RAMs); quantum electronics as in the here used quantum wires (QWs) allows a multi-level logic in one memory cell (current on/off in several steps, sharply distinguishable measurable ideally) and thus a much higher storage density.

### “State of the Art”

Power transistors/switches are based nowadays on bipolar (pn-) junctions (thyristors) or optimized MOSFETs with certain power losses and time constants [12].

Even though in MOSFETs 2-DEGs play a role, they are in general not considered quantum electronic transistors, mainly because single electron effects are not occurring, the “grainyness” of the charge [carriers] does not play a role.

Quantum electronic transistors (single electron transistors—SET) have already been predicted theoretically for a long time and experimentally demonstrated (e.g. [13], [14] and references therein), mostly by solely exploiting the Coulomb blockade (charge quantization) based on the 0-dimensional confinement of the electron (size of the QD smaller than the mean free path/scattering length of the electron in the material) in a very small metallic or semiconducting nanoparticle/compartment/“box”, mostly at extremely low (a few Kelvin) temperatures, (but partly also at room temperature in the case of molecules as nanoparticles), gated mostly by a variable static electric field. In more recent times also CNTs (where SWCNTs actually constitute quantum wires, as is generally—perhaps/supposedly not always correctly—accepted) and other molecules gated by an electric field have been demonstrated as SETs at room temperature (e.g. [15], [16] and references therein, [17]), but to best of my knowledge, in those cases, there was never observed true transmission through 1-dimensional quantum states (staircase I-V-curve and conductance peaks in the source-drain-I-V-curve along the nano wire) at room temperature In [14], actually Aharanov-Bohm oscillations were described within a 1-dimensional metallic cylinder, at extremely low temperatures (about 1 Kelvin) though, which are only visible in an approximately 1-dimensional ballistic conductor. Logic circuitry by usage of CNT-nanowires have been presented already also in [17a].

Nanowire arrays in the form of nano wires electrically connected in parallel, e.g. CNTs, controlled/switched by an electric field (gate electrode) have also already been suggested as power transistors [18], (but significantly before in [23] by myself), but was in [18] so far only realized with some 300 CNTs, which would result in only 3 μA (maximum of 10 nA per nanowire at crudely assumed 100 nm length, roughly the minimum to be able to speak of approximately 1-dimensional conductivity in a nano wire of about a few nm diameter) controllable load current. Quantization effects and their applications are not claimed there in [18], the vertical growth method aiming at obtaining 2-dimensional arrays of vertical nano wires as in [18] and similarly proposed in [10], supposedly does not deliver SWCNTs, only the much wider MWCNTs, which do not show any quantization effects at room temperature, at most a moderate Coulomb blockade (solely charge quantization, quite often trivially caused by small capacities in the junction/material transition or electrical contacts, no real 1-dimensional conductance quantization.

Regarding data storage, the generally known state of the art is as follows: In the case of GMR-harddiscs the current through a locally magnetized (writing of the bits) layer is measured by means of a read-write head, and thus the bits are read. In the case of DRAMs and Flash RAMs, the charging state of a very small capacitor is measured via a matrix circuitry similar to a CCD-array. In the case of SD/SDHC-cards, I honestly do not know, but probably it is closely related to the concept of Flash-RAMs.

### Solution

Quantum electronics can solve these problems concerning power losses/heat generation and time constants and all that by at the same time allowing a multi level logic with much higher data storage density. This is possible, since ballistic electronic conductivity, and especially the transmission of an electron wave along a 1-dimensional quantum state, i.e. eventually the load current in a quantum electronic transistor/switch occurs without Ohmic resistive losses (R=0 theoretically ideally) as well as the direct, extremely sensitive control/switching of the quantum electronic elements, occurs loss-less and practically instantaneously. The “gate” of a quantum transistor has to be mediated via an electromagnetic field (magnetic, optical, electric, electro-acoustical) and solely the generation of this small controlling field determines power loss and time constant of this transistor/switch. Additionally there is no mechanical contact and no contact voltages in such a quantum mechanical transistor/switch between the gate and the quantum mechanical source gate element. Certain contact resistances obviously occur at the (tunnelling-) contact junctions between single quantum wires and the source-drain electrodes, which are in turn necessary, so that the 1-dimensional quantum state is able to exist at all; these tunnelling- transition/contact resistances have to be at least some 10 kOhm, dependent on the tiny capacitance of the single QWs and on the desired sharpness of the quantum conductance peaks in the I_{sd}-U_{sd}.curve (at least 25.8 kOhm are resulting from Heisenberg's uncertainty principle). In the case of the here invented power transistor are all these resistances as well as the “resistances” of the QWs themselves (i.e. (reflexion+absorption)/transmission) in parallel, so that the total resistance is thus small.

The here invented power transistor connects about 10¹⁰/cm² vertical and parallel with respect to each other directed quantum wires electrically in parallel and controls the ballistic source-drain current through these nano wires collectively or variably in the single wires. At a current of order on 1 nA through one QW a controllable current of 10 Amperes is resulting at a component size of roughly 1 cm², where the manufacturing method of the quantum wire array [1] in an heavy ion accelerator (e.g. GSI Darmstadt or Ganil/CIRIL, Caen, France) so far at maximum about 25 cm²×10¹¹ cm⁻² (equivalent to roughly 2.5 kA maximum controllable total load current) QWs can be realized, which are electronically independent from each other in the 2-dimensional array. It is emphasized, that the current does not have to be equal in each QW, but also can vary via intended inhomogenuities of the gate field across the total component area and eventually also is supposed to do so. By spatial variation of the gate field the I_{sd}-U_{sd}-characteristics of the complete power transistor can be tailored in a certain range. By means of scanning probe microscopy (SPM) or e.g. by means of by SPM structured gate field sources (ferromagnetic or ferroelectric layers—see above) it will obviously be possible to switch only particular single or groups of several QWs in the array specifically, which can be addressed one by one or group by group using micro-/nano-structured electrodes on preferably the “upper” side of the array (see [1]), because on the lower side is the solid support wafer/material but using modern layer technology, the structured side could also be on the lower electrode side in principle. Manufacturing of such minute electrode structures (10 nm-scale) is possible via electron beam lithography or scanning probe lithography, and the newest imprinting methods and optical masking/exposure techniques (XUV) also reach into the 10 nm-scale.

The size limit for the 2-dimensional quantum wire array manufacturing imposed by the design of the heavy ion accelerator is roughly 25 cm² but can be overcome (if necessary at all) in principle using a beam scanning technique [19] at the cost of longer irradiation duration (order of magnitude is about 30 minutes for 10¹¹ single swift heavy ion impacts per cm² instead of only a few minutes normally for 10¹⁰ ion tracks per cm² on a 25 cm²-sample using the ion beam expanded to 25 cm². The QW-density of at maximum about 10¹¹/cm² results in a mean separation of the QWs of about 30 nm from QW to QW. At a particle track diameter of significantly below 5 nm (probably roughly 1-2 nm, probably even smaller, see [1]) and an effective quantum wire diameter of <1 nm (conductance peaks at room temperature, FIG. 4), the QWs are then obviously still sufficiently electronically independent. However, it is most likely impossible to position the QWs even closer than that due to electronic overlapping effects and other unwanted radiation damage in the insulating matrix during the generation of the particle track QWs (scattering/impacts with secondary ions/electrons/x-rays) and especially due to larger local radiation damages on/at the surface/interfaces. If, however, a thin source electrode is deposited already before the irradiation with the single swift heavy ions, then the radiation damage at the interface between the DLC-layer matrix in which the particle track QWs form will be certainly less than on a naked DLC-surface and thus a maximum density of the vertical QW-array of 10¹²/cm² is supposedly achievable in principle—however, at regular (as above) fluence of the swift heavy ions' beam the irradiation time duration goes up to about 5 hours, up to date machines certainly have higher beam currents than in 1999 though.

The manufacturing method of the QWs firmly embedded in for instance a DLC-film (as described in [1]) further exploits the here much desired property of diamond of extremely high heat conductance and transparency for light. Thus, in the case that if due to a malfunction in the here invented power transistor suddenly the “Ohm-less” electrical conductivity breaks down in one or many QWs of the large array, due the excellent heat diffusion in the insulating diamond-like matrix, a complete destruction of the power transistor/component probably gets prevented; supposedly only a few single QWs would get destroyed in such a case, which would hardly play a role at 10¹⁰/cm² QWs in the array.

### Explanations for the Patent Claims

1. Power transistor, -switch, -photodetector, -solar cell, specified in that it is:

A quantum wire array power transistor QFET (quantum FET): 2 dimensional array of very many densely packed, vertical or up to 30 degrees—also in groups with respect to each other—tilted, in an insulating matrix embedded parallel and—also in groups—electrically parallel connected QWs, which interconnect source and drain contacts of the QFET and function at room temperature, collectively controlled/switched or one by one wire/wire-group by a electromagnetic field (static or dynamic). Especially it is hereby claimed, that the (so manufactured as in [1]) quantum wires exhibit in particular at room temperature a (here in this invention usable/applicable) staircase-I-V-curve along the quantum wire (i.e. current I_{sd} along the QWs as a function of the source drain voltage U_{sd}, FIG. 2 at room temperature), not just as a function of a gate voltage U_{g} (which could already be caused by mere Coulomb blockade effects, i.e. mere charge quantization effects as opposed to quantized conductance/transmission through 1 dimensional quantum states). Especially it is further claimed the occurrence and usage in this invention of the quantum conductance peaks (here manifested in form of extremely sharp peaks in the current I_{sd}) in this I_{sd}-U_{sd}-characteristic (measured along the “true” QWs) within the current suppression plateau (in the vicinity of 0 volts, where the current I_{sd} versus U_{sd} is suppressed as usually by the Coulomb blockade—but here also by the conductance quantization effects) (FIG. 4, at room temperature) “along” the QW; quantum conductance peaks are sometimes also visible at higher voltages U_{sd} outside the Coulomb suppression plateau. These source-drain characteristics I_{sd} versus U_{sd} “along” such a “true” quantum wire can be very sensitively and rapidly modulated/controlled/switched by applied external “gating” fields (magnetic, electric, optical, electro-acoustical)—FIG. 3 electrically/magnetically/electro-acoustically and FIG. 10 optically, all at room temperature-, because they are caused by 1-dimensional transmission through quantum states [2,3,4].

If these “true” QWs in an 2-dimensional array are manufactured very identical, these characteristics in the source-drain I_{sd}-U_{sd}-curve of a single QW should also qualitatively occur in the entity of the electrically parallel connected QWs, especially if source and drain electrode are ideal conductors as well (e.g. 2-DEGs at room temperature, SCs at low temperatures or as a compromise thin crystalline metal films at moderately lowered temperatures).

2.Power transistor according to major patent claim 1, specified in that, that:

the source-drain current is modulated/controlled/switched via a magnetic field by means of variable current in a coil surrounding a soft iron core (tip or structured), spatially closely above the QW array, as well as by its distance to the QW-array (FIG. 6) or by the current through a meander-shaped conducting lead closely on top or underneath the QW-array or embedded within the QW-array.

3.Power transistor according to major patent claim 1, specified in that, that:

the source-drain current is modulated/controlled/switched via a magnetic field by means of depositing and appropriately magnetizing (e.g. by writing onto using above magnetic tip mounted to a SPM) a ferromagnetic layer on the 2 dimensional quantum wire array, e.g. Fe, Co, Ni or a layer from polarisable ferromagnetic nanoparticles (Fe, Co, Ni), i.e. a power transistor with non-volatile memory effect of the transistor-working point and the source-drain-I-V-characteristics (FIG. 7).

4. Power transistor according to major patent claim 1, specified in that, that:

the source-drain current is modulated/controlled/switched via an electric E-field by means of an electrically (-statically) charged scanning probe tip or by means of depositing onto or embedding into the 2-dimensional QW array and appropriately polarizing (i.e. by means of an electrically strongly charged tip mounted to an SPM) of a ferroelectric as well as an antiferroelectric layer, or by means of applying a lateral voltage (electric field) in this polarisable thin film, for instance an appropriate liquid crystal layer of polar molecules or of a layer of polar nanoparticles, just as in 3. with non-volatile memory effect of the transistor working point and the source drain-I-V-characteristics (as in FIGS. 6 and 7).

5. Power transistor according to major patent claim 1, specified in that, that:

the source-drain current and its I_{sd}-U_{sd} characteristics is modulated/controlled/switched by means of irradiation/illumination an electromagnetic field (e.g. IR-light, visible light, UV-light, X-rays) onto the 2-dimensional QW-array (photodetector) (FIG. 9).—according to light sensitive characteristics of a single QW (FIG. 10).

6. Power-quantum wire array solar cell in design and fundamental function identical with patent claim 1. and patent sub claim 5. which is specified in that that:

under exposure to light at 0 Volts U_{sd} is flowing a non-zero current which means light energy is converted into electrical energy.

7. “Artificial retina”: The QWs in the array are electrically contacted one by one, the “light-effect” on the single drain current in single QWs in the extremely large and dense array (up to roughly 10¹⁰-10¹² QWs per cm²) could be read out dependent on the location of the single illuminated QW's and thus can be used in highest resolution electronic cameras. As already mentioned, using modern (current) lithography methods the necessary small structure widths can be realized theoretically, for instance in order to manufacture a resistor cascade as in an shift register.

8. Power transistor, -switch, according to patent claims 1-5 or solar cell according to claim 6, specified in that that:

source and drain electrodes consist of an ideally conducting layer (e.g. crystalline metals at moderately low temperatures, super conductors at low temperatures or 2-DEGs at room temperature), where through phase shift effects of the electronic wave functions the sensitivity/efficiency of the transistor gating/gain respectively the solar cell's efficiency can be drastically enhanced. This further represents a model system for a 1-dimensional/1-directional pseudo-super conductor at (at least almost) room temperature.

9. Transistor (quantum memory cell, QMC) analogously to patent claims 1, specified in that that:

the source-drain current of only one or a few parallely connected “true” QWs is controlled/switched and is used as a non-volatile, (re-) writable memory cell, analogously to the proposal in [1], just differing in that that instead of the B-field generating QUID there for dynamic (i.e. volatile) switching writing/reading out of the quantum transistor, here now an “elementary magnet” in a ferromagnetic film or a ferromagnetic nanoparticle above one terminal of the QW/QWs is used for writing of the state of the QW/QWs, which could for instance be “set” (magnetized) by the magnetic tip of an SPM, or by the writing head of a HDD—analogously, a electric field “setting” of the QWs' quantum states as in patent claim 4 is possible. This would be a storage technique for a new-fashioned computer mass storage device, where the 2-dim. QWs' array read out by measuring currents through the single QWs or small groups of parallel QWs could be rotating (underneath a (current) reading head) just like in up-to-date on GMR-effect based HDDs; or, a stationary read out would be possible using one or many parallel write/read scanning probe tips (electrically conducting and simultaneously serving as a source for a local magnetic /electric field). “Many” probe tips, i.e. an array of probe tips is similar to [20], but there, the stored information is exclusively read (and of course also written) via the cantilevered probe tip, while here in the present invention the probe tip(s) are primarily serving only for writing and erasing of the QW-currents-controlling ferromagnetic/ferroelectric bits (with multilevel logic eventually). Further the QW array can also be read out via a stationary “intern” current measuring (matrix) integrated on or into the QW-array—similar to the read-out method in a DRAM or Flash-RAM (here just a current detection instead of a voltage detection)—while however obviously the currents through a QW can be measured most easily via electrically conductive probe tips, analogously to a currently used GMR-HDD. A way, how the read out of the QW-matrix via an intern current measuring matrix can be realized, is described/suggested in [1], where still the connection with a resistor cascade matrix probably similar to the one in a DRAM, Flash-RAM, CCD-array is needed.

By means of the staircase characteristic (I_{sd} versus U_{sd}-curve) and the quantum conductance peaks in I_{sd} versus U_{sd} a multilevel-logic becomes realizable, using many parallel quantum wires perhaps a multilevel-power quantum field effect transistor (power QFET) becomes realizable, which is characterised by an extremely low leakage /rejection current. The noise floor for the current measurement is of order pAmpere.

Non-volatility for this here invented QMC is not quite analogous to DRAM (volatile) and Flash-memory (non-volatile), because at switched off power supplies the as currents stored (order nanoAmperes) information temporarily disappears, but the working point on the I_{sd}-U_{sd} characteristics remains stored in an non-volatile manner due to the ferromagnetic/ferroelectric (locally “written” by structuring the gate) gate and is immediately accessible again, once the power is switched back on, of course only at exactly the same U_{sd}, where such a here invented multilevel power transistor (quantum FET) could serve as a stable and super accurate power supply.

Patent claim 9 differs and is distinguished from the multiply in the literature suggested nanowire-FETs, also from the (MW)CNT-FETs (a FET realized by a single nanowire/quantum wire—e.g. a CNT) in that that:

Firstly the here invented singular quantum wire transistor can be controlled/gated by a magnetic field and not just by an electric field (the present invention transistor of course can also very well controlled/gated by an electric field),

Secondly, a multilevel logic according to the staircase and the quantum conductance peaks in the I_{sd}-U_{sd}-characteristics in FIGS. 2, 3, and 4 at room temperature is realizable, and thus

Thirdly, in that that here actually in fact at room temperature a 1-dimensional ballistic current (even transmission current through a 1-dim. Quantum state and not through a zero-dim. Quantum dot) through a “true” quantum wire is controlled and not just largely an Ohmic current superimposed by Coulomb blockade effects (single electron effects, i.e. mere charge quantization, not conductance quantization) with, due to confinement somewhat reduced scattering at the walls of the nanowire, which is very small though, but in comparison to the Fermi wave length (roughly a few Angströms in metallic conductors at room temperature) of the electron the nanowires' lateral dimension is still huge, at least at room temperature (since in a metal, scattering length goes up with temperature, while Fermi wavelength remains the same)—whereas in a true quantum wire its lateral dimension has to be of order of the electron's Fermi-wavelength in the material. A nanowire just based on charge quantization (i.e. without conductance quantization in the I_{sd} versus U_{sd} characteristics) supplies a staircase curve I_{sd} versus U_{gate} but most likely not a staircase curve I_{sd} versus U_{sd} (FIG. 2) and by no means quantum conductance peaks (here manifested by extremely sharp peaks in the current I_{sd}) in the Coulomb blocked current suppression plateau around zero Volts as visible in the I_{sd} versus U_{sd} characteristics along the here shown “true” quantum wire (FIG. 4). These “unusual” effects are also addressed in similar manner in [22], also here I_{sd} is plotted versus U_{source-gate}, where in the set-up of the present invention also it can be assumed, that U_{sd} is leaking into the electrically insulating matrix and is responsible for the fact, that the quantum conductance peaks are slowly drifting back and forth along the U_{sd}-axis. In other words: U_{sd} and U_{source-gate} “mix” in the case of CNTs always, and the more the shorter the nanowires are.

All these effects are not touched in [21] for instance, neither in work, known from the literature, on nano wire (E-) field effect transistors (z.B. [15], [17]).

10. The experimental set-up in FIG. 1 for the recording of the characteristic I_{sd}-U_{sd}-curves of single quantum wires contains a protective resistor (8) between the combined STM/AFM-probe tip and the function generator which is the voltage source for U_{sd}. The chosen resistance depends on the specific tip and nano wire properties and lies in the ranges of roughly 100 kOhms-1 Mohms or 1 Mohms-10 Gohms.

### REFERENCES

[1] EP1096965A1, F. Ohnesorge et al

[2] “Record of the international Symposium on the electron and the electromagnetic field in Nanometer-scale structures” H. Nejo (Ed.), Springer 2000

[3] H. Akera, T. Ando, Phys. Rev. B, 11676 (1991)

[4] “Mesoscopic Physics and Electronics” T. Ando et al. (Eds.) Springer 1998

[5] G. M. Mikhailov et al. Nanotechnology 9, 1, (1998)

[6] zurückgehend z. B. auf H. Weman et al., Phys. Rev. B 48(11), 8047 (1993)

[7] A. Gossard et al, Phys. Rev. Lett. 80(20), 4522 (1998)

[8] R. A. Jalabert et al., Phys. Rev. Lett. 68(23), 3468 (1992)

[9] EP0408966

[10] U.S. Pat. No. 6,566,704,B2 Wun-bong Choi et al.

[11] B. H. Hong et al., Science 294, 348 (2001)

[12] z. B. “Leistungselektronik”, R. Felderhoff, Hanser ISBN 3446402616, 2006, oder z.B.: “Leistungshalbleiter-Handbuch. Mit Leistungs-MOSFETs”, J.C. van de Ven, ISBN: 3922705464

[13] M. H. Devoret et al. Ultramicroscopy 42-44, 22 (1992)

[14] B. Kramer, Physikalische Blätter 50(6), 543 (1994)

[15] S. J. Tans, A. R. M. Verschueren, C. Dekker, Nature 393, 49 (1998)

[16] C. Joachim, J. K. Gimzewski, A. Aviram, Nature 408, 541 (2000)

[17] H. W. Ch. Postma et al., Science 293, 76 (2001)

[17a] A. Bachtold et al., Science 294, 1318 (2001)

[18] DE102004003374A1 F. Keupl et al.

[19] B. Fischer, Rasterscan-Verfahren, GSI Darmstadt

[20] U.S. Pat. No. 5,835,477, G.Binnig, H. Rohrer, P. Vettiger “Mass-storage applications of local probe arrays”

[21] DE10036897C1 J. Kretz et al.

[22] J. Appenzeller et al. PRL92(22), 226802 (2004).

[23] The not pursued (and not disclosed) patent application with the DPMA #DE10019040.5 of Apr. 18, 2000 (Frank Ohnesorge: “Room temp. superconductor, application as power transistor”) already contains the central statement on realizing a power transistor by means of an array of many electrically parallely connected quantum wires and the right for originality is thus claimed on this date. The same holds for DE10019039.1 (Frank Ohnesorge: “Artificial retina”) of Apr. 18, 2000.

### DRAWINGS

FIG. 1: Experimental set-up for proving quantized conductivity in the nano wires (generated by particle tracks, caused by single swift heavy ions). The tip of a combined AFM/STM is line by line raster-scanned across the surface, and locally the current through the quantum wires at their terminals recorded. For measuring the I_{sd}-U_{sd}-characteristics the scan is stopped and the drift at room temperature allows a stable measurement of the characteristics for about 10 seconds, before the electrically conducting probe tip has to be readjusted. Claimed here in this FIG. 1 is the protective resistor R_{protection} between function generator (U_{sd}) and STM/AFM tip.

FIG. 2: I_{sd}-U_{sd}-characteristics (“steps”) of single quantum wires at room temperature: The Fermi level of the (semi-) conducting tip scans (scanning of U_{sd}) the quantum states of the quantum wire, the little steps in [1] in the U_{sd}-I_{sd}-characteristics, the large steps are supposedly the scanning states of a tiny grain at the end of the probe tip or the hillock-like ion track on the DLC-surface as a quantum dot (order 0.5 nm), which are necessary to make the thin needle-like peaks in I_{sd} in FIG. 4 visible, where U_{sd} simultaneously shifts the quantum dot levels, i.e. represents the gate voltage U_{sg} for the quantum dot at the same time.

FIG. 3: Field-modulated I_{sd}-Uₛₑcharacteristics of single quantum wires at room temperature—the enveloping curve is again the staircase characteristics and it is remarked, that the current modulation goes down all the way to zero nA (noise floor of order pA).

FIG. 4: Cut-out section of I_{sd}-U_{sd}-characteristics in the current suppression plateau near U_{sd}=0V at room temperature. Exactly vertical quantum conductance peaks, here manifested by needle-like current peaks in the drain current I_{sd}; they occur with a “height” of up to 1 nA at U_{sd}<<50 mV. (It is remarked, that the tunnelling contact resistances between and quantum wire as well as between the AFM/STM probe tip and the quantum wire are still unknown/undetermined). These current peaks manifest electronically measurable the physics of the wave mechanical transmission of few electrons through the quantum wire's 1-dimensional quantum states.: Supposedly the upper most occupied quantum state of a quantum dot (sort of a HOMO), a conductive tiny grain at the probe tip or the ion track on the DLC-surface scans (by tuning U_{sd} up and down) the quantum states of the quantum wire (finding the peaks in a 2 mV separation).

FIG. 5: I_{sd}-U_{sd}-characteristics without quantum wires, only the electrically conductive probe tip in contact with electrically conductive (B-doped) diamond layer, also at room temperature.
Magnetic field /E-field controlled/gated QuantumFET.

FIG. 6: Embodiment 1: Power transistor—drawn are only 3 quantum wires, there is however at least 10¹⁰/cm² up to theoretically possible 10¹²/cm².

FIG. 7: Embodiment 2: Power transistor with “memory”
Embodiment 3a and 3b: analogous to as shown in FIGS. 6 and 7: non-volatile and (re-) writable memory cell element, consisting only of one single or up to very few parallely connected quantum wires.

FIG. 8: (partial) cross section view of FIG. 7.
Embodiment 4: Optically modulated power transistor, photo detector, solar cell

FIG. 9: Scheme Solar Cell/Photodetector

FIG. 10: I_{sd}-U_{sd}-characteristics “illuminated” and “dark” at room temperature.

FIG. 11: Embodiment 5: el.-magn. field-controllable/gate-able power transistor, photo detector, solar cell with drastically optimized sensitivity by introducing ideally conducting (R=0) layers as source drain electrodes, e.g. crystalline metals or superconductors at low temperatures, especially however 2-DEGs at room temperature at the hetero junction between the DLC-film and source drain electrodes. Model system for a 1-dimensional (1-directional) (pseudo-)superconductor at room temperature.

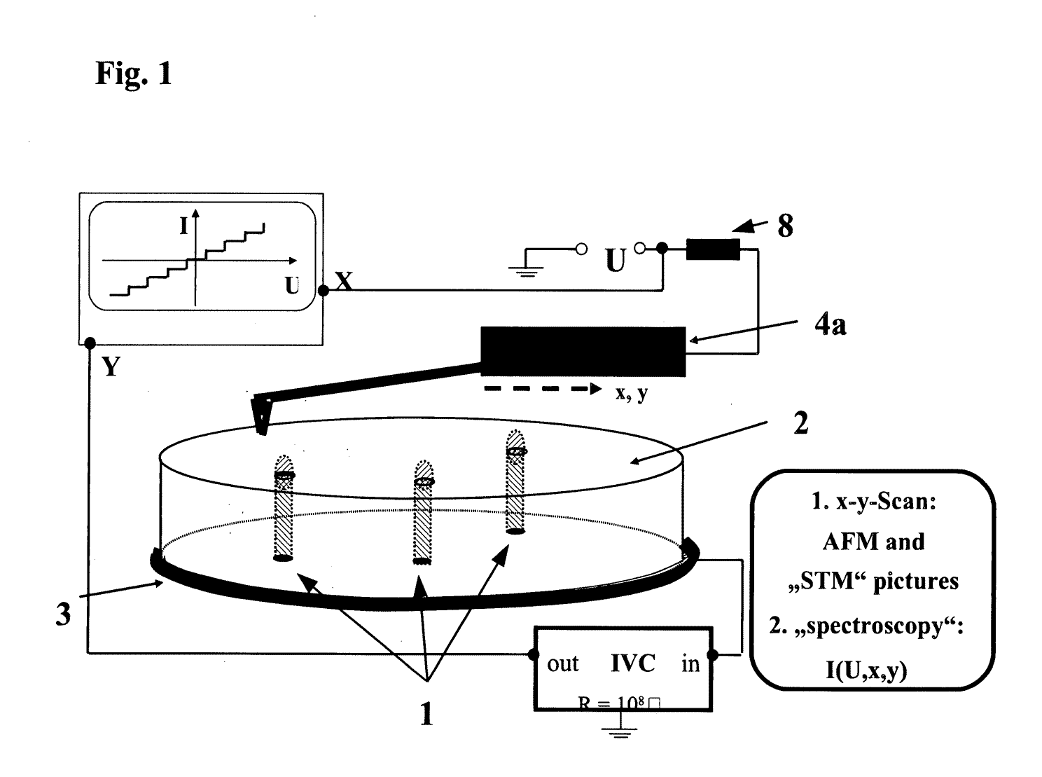

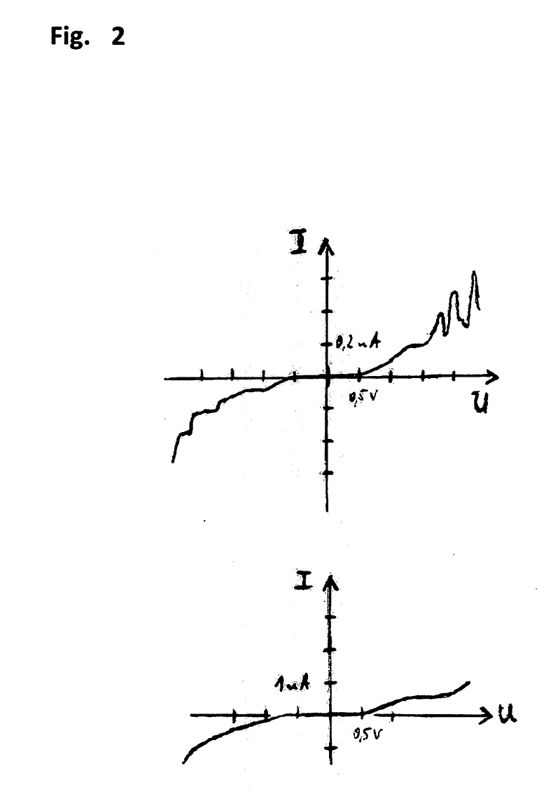

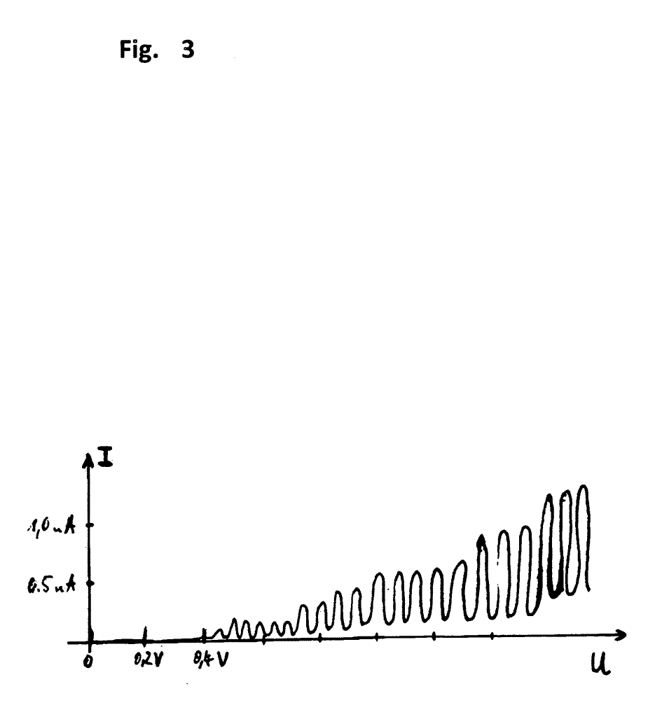

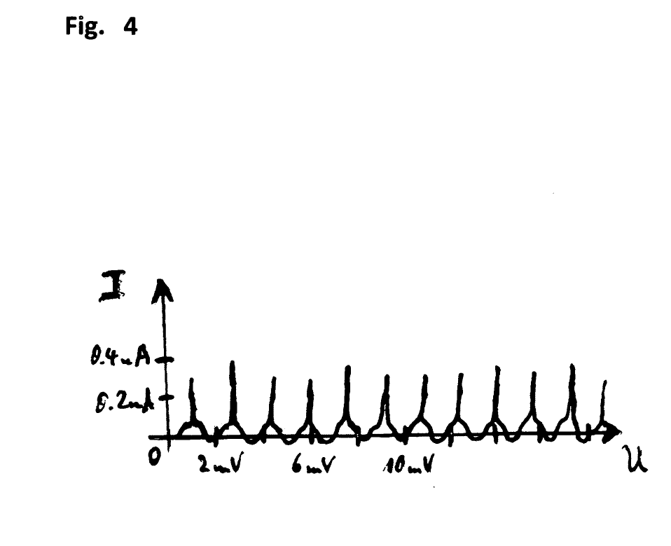

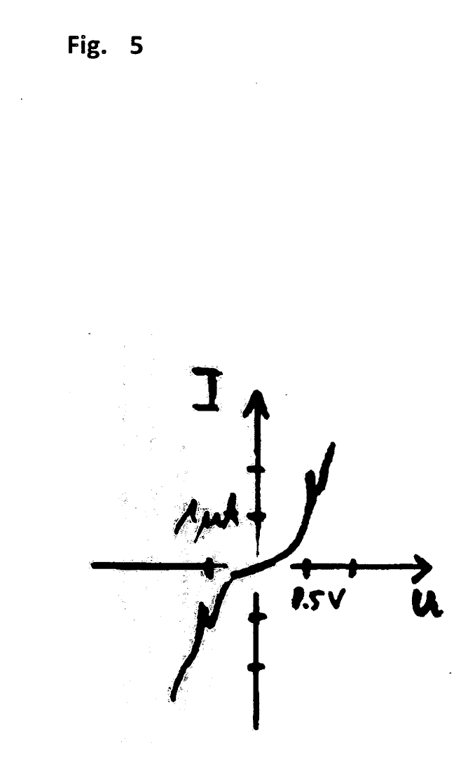

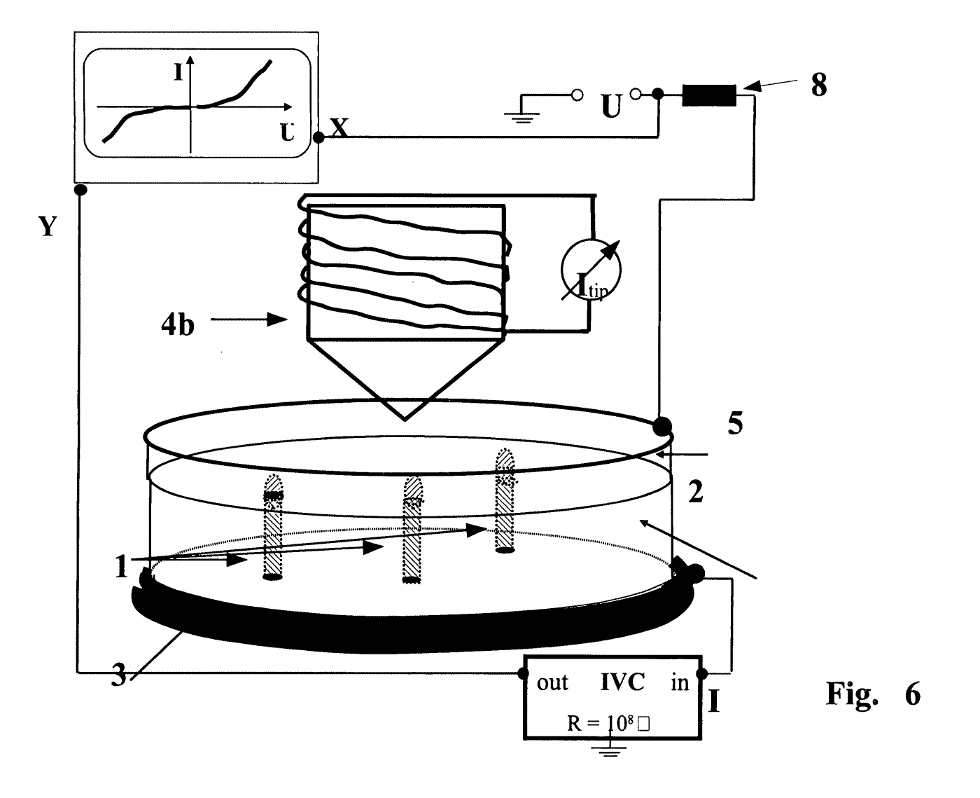

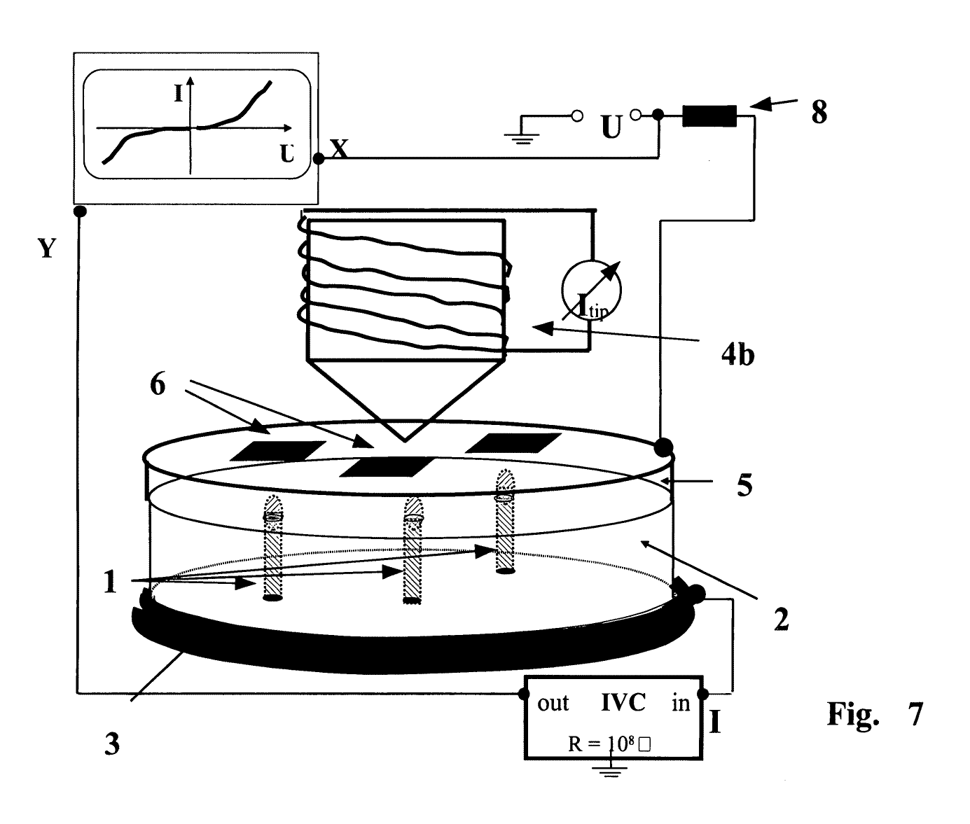

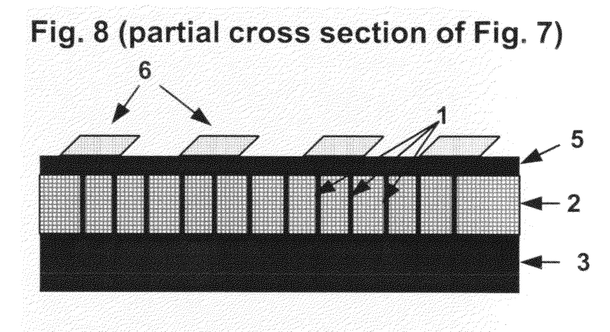

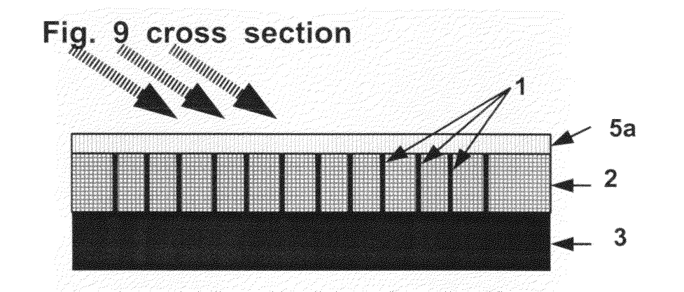

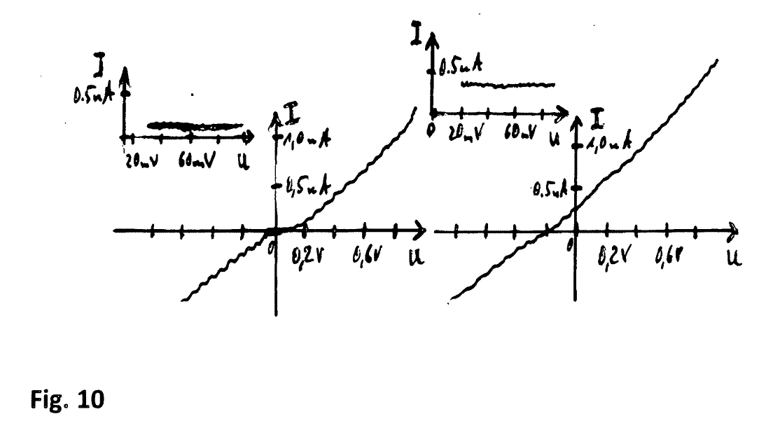

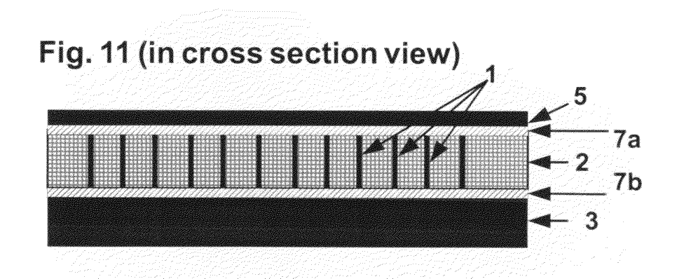

### LEGEND OF THE NUMBERING IN THE FIGURES

1. Quantum wires generated by the through-passage of single high energy ions [1]

2. Electrically insulating matrix which is embedding the quantum wires and in which they were generated, e.g. DLC (resistivity 10¹² Ohms×cm), SiC, polymer, see [1], approximately atomically flat.

3. Electrically well conducting almost atomically flat substrate, e.g. highly doped Si-wafer.

4a. AFM probe cantilever carrying an electrically well conducting probe tip (B-doped diamond).

4b. Magnetic tip of a size scalable with the desired component size/capability, which can also strongly charged electrostatically.

5. Source-electrode layer, electrically well conducting material, e.g. metal film, at best crystalline (z.B. Au, Pt, Pa, Cu) or highly doped (e.g. with B, or P, N) semiconductor material (e.g. Si, GaAs, highly doped—for instance with boron—diamond-like carbon (DLC)).

5a. Source-electrode layer, transparent for the application of the optical transistor control/of the solar cell, e.g. extremely thin metal films, at best crystalline, or for instance ITO-glass (amorphous), or highly doped electrically conducting DLC, transparent for IR.

6. polarized/magnetized ferroelectric/ferromagnetic dipole (“elementary magnets”), deposited as a thin film on the source electrode.

7. 7. (Preferably) bias-voltage-less 2-DEGs, proposed for the hetero junction between

DLC-film and the source electrode (7a) between DLC-layer and the drain electrode (7b), where a suitable highly doped semiconductor material for source and drain electrode has still to found such that the 2-DEGs are formed on both sides of the DLC-layer.

8. protective resistor 100 Ohm-1M Ohm respectively 1 M Ohm-10 G Ohm.

### ABBREVIATIONS

AFM—atomic force microscope

CNT—carbon nano tube

DLC—diamond like carbon

DRAM—dynamic random access memory

FET—field effect transistor

GMR—giant magneto resistance

I_{sd}—(source-) drain current

MWCNT—multi-walled carbon nano tube

QD—quantum dot

QUID—quantum interference device

QW—quantum wire

SC—super conductor

SET—single electron transistor

SiC—silicon carbide

SQUID—superconducting quantum interference device

SWCNT—single walled carbon nano tube

U_{gate}—gate voltage versus arbitrary ground

U_{sd}—source-drain voltage

U_{source-gate}—voltage between source and gate

2-DEG—2 dimensional electron gas

1. Power transistor, switch, solar cell, light pixel sensor array or quantum field effect transistor characterized in that
it is a quantum wire array field effect transistor comprising
a 2 dimensional array of up to 10¹⁰-10¹² geometrically parallel quantum wires per cm² comprising at least one quantum wire electrically interconnecting source and drain contacts of said quantum wire field effect transistor,
or comprising groups of quantum wires that are connected electrically parallel interconnecting source and drain contacts of said quantum wire field effect transistor or comprising all quantum wires electrically parallel interconnecting source and drain contacts of said quantum wire array field effect transistor,
where the quantum wires are vertical or can be tilted up to 30 degrees, also in groups,
where the quantum wires are fabricated by passage of swift heavy ions through an electrically insulating layer of DLC or SiC or polymer,
where these quantum wires are SWCNTs,
where these quantum wires connected in parallel exhibit 1-dimensional quantum mechanical ideal conductivity,
where these quantum wires are characterized in that
they exhibit also at room temperature a stair case I-V curve (9) source drain current I_{sd} versus source drain voltage U_{sd} along each quantum wire of the quantum wire array by means of which the current can be switched in steps,
further that these quantum wires exhibit quantum conductance peaks (11), which are extremely sharp peaks in the current I_{sd} in this I_{sd} versus U_{sd} characteristics along each quantum wire of the quantum wire array in the I-V curve's plateaus, especially also across the Coulomb blockade current suppression plateau at 0 Volts, which here is additionally suppressed by conductance quantization effects,
further that these quantum wires exhibit I-V curves characterized by the fact that these I_{sd} versus U_{sd} curves can be sensitively modulated by applied external controlling gate fields—magnetic or electric or electro-acoustic according to the field modulated staircase I-V curve (10) and optical according to the light sensitive I-V curve (12),
further that the presently invented transistor consists of quantum wires that are identical such that the I-V characteristics of each single quantum wire of the quantum wire array holds qualitatively also for the entity of the electrically parallel connected quantum wires, further that the presently invented transistor's transistor characteristics can be tailored by adjusting the strength and inhomogenuity of the gate field,
where differently strong and differently directed gate fields act locally on each quantum wire of the quantum wire array or groups thereof, by means of which every single quantum wire or every group of quantum wires obtains a different I-V-curve resulting in a tailored mean total I-V curve I_{sd total} versus U_{sd total} of the transistor.

2. Power transistor according to patent claim 1 characterized in that
the source drain current and its I-V characteristics in the quantum wires and in the quantum wire array in this operational mode is controlled by a externally applied magnetic field,
where by means of a variable current in an inductance surrounding an soft-magnetic iron core (4b), spatially closely above the quantum wire array and by means of its separation from the quantum wire array the magnetic field in the quantum wire array is controlled,
or where by means of a variable current strength through a meander shaped circuitry enveloping/around the single quantum wire terminations the controlling magnetic gate field is adjusted,
where the current I_{sd} through the quantum wires and I_{sd total} through the power transistor can be controlled in steps,
where in both above cases an external inhomogeneous but spatially and in terms of strength defined magnetic field is generated across the quantum wire array, which thus exhibits a adjustable inhomgenuity that can be changed over time and thus allows tailoring of the total I-V curve of the presently invented power transistor,
whereby source and drain electrodes (3,5) may be ideal electric conductors as well, such as 2-DEGs at room temperature (7a,7b) or superconductors at low temperatures or thin crystalline metal or semiconductor at room temperature or moderately lowered temperatures.

3. Power transistor according to patent claims 1. and 2., characterized in that
the source drain current and its I-V characteristic in the quantum wires and the quantum wire array is controlled or switched by an externally applied magnetic field by means of depositing and suitably magnetizing a ferromagnetic layer (6) on top of the quantum wire array by writing on the ferromagnetic layer (6) with a magnetic tip (4b) mounted to a scanning force microscope or with said meander structured circuitry,
where the ferromagnetic layer (6) consists of Fe or Co or Ni or a layer of ferromagnetic nanoparticles of Fe or Co or Ni,
where a non-volatile memory effect of the transistor working point and the source drain I_{sd}-U_{sd} characteristics is achieved,
further characterized in that the transistor's source drain I-V characteristics can be tailored by microstructurally magnetizing the ferromagnetic gate field generating layer, by means of which a defined inhomogenuity of the gate field across the quantum wire array is achieved.

4. Power transistor according to patent claim 1, characterized in that
the source drain current and its I-V characteristics can be controlled or switched by an externally applied electric field by means of a electrically charged scanning probe tip, and or by means of depositing or embedding into the quantum wire array and suitably polarizing of a ferroelectric or antiferroelectric layer or by applying a lateral voltage within that ferroelectric or antiferroelectric layer, the transistor working point and the source drain I_{sd}-U_{sd} characteristics can be tailored with non-volatile memory effect,
where the source drain I-V characteristics can be tailored by microstructural polarizing of the ferrorelectric or antiferroelectric gate field generating layer, whereby a defined inhomogenuity of the gate field across the quantum wire array is generated,
where the ferroelectric layer consists of a liquid crystal layer of polar molecules or a layer of polar nanoparticles,
whereby source and drain electrodes (3,5) may be ideal electric conductors as well, such as 2-DEGs at room temperature (7a,7b) or superconductors at low temperatures or thin crystalline metal or semiconductor at room temperature or moderately lowered temperatures.

5. Power transistor or power switch or solar cell according to patent claim 1, characterized in that
the source drain current and its I-V curve in the quantum wires and the quantum wire array is modulated or controlled or switched by external irradiation of electromagnetic radiation such as infrared or visible or ultraviolett or x-ray onto the 2-dimensional quantum wire array,
where the quantum wire array then acts as a photodetector according to the light sensitive I-V curve (12) of a single quantum wire of the quantum wire array,
where by means of a quasi constant but time-variable inhomogenuity of a light intensity distribution across the quantum wire array the I-V characteristics of this optically gated transistor can be tailored,
whereby source and drain electrodes (3,5) may be ideal electric conductors as well, such as 2-DEGs at room temperature (7a,7b) or superconductors at low temperatures or thin crystalline metal or semiconductor at room temperature or moderately lowered temperatures.

6. Power quantum wire array solar cell according to patent claims 1. and 5., characterized in that functional feature
that under exposing to light at 0 V source drain voltage a non-zero source drain current (12) is detected and light energy is converted into electrical energy, where the source electrode consists of transparent electrically in the ideal case ideally conductive material,
where this said material is indium tin oxide or a thin electrically conductive metal or semiconductor layer which are as an alternative in the ideal case forming also a 2-DEG (7a,7b) with the diamond like carbon film or superconductors at low temperatures or thin crystalline metal or semiconductor films at room temperature or moderately lowered temperatures.

7. Light pixel sensor array comprising electrically connected quantum wires according to the functional feature light sensitivity of the quantum wires' I_{sd}-U_{sd} curve according to patent claim 1,
where this operational mode is characterized in that
the single quantum wires are contacted each separately and the light effect on the single source drain currents in the single quantum wires of that up to 10¹⁰-10¹²/cm² quantum wire array is read out position dependent,
where the single source or drain electrodes consist of transparent conductive material such as indium tin oxide or a thin electrically conductive metal or semiconductor layer which are as an alternative in the ideal case forming also a 2-DEGs at room temperature (7a,7b) with the diamond like carbon film or superconductors at low temperatures or thin crystalline metals or semiconductors at room temperature or moderately lowered temperatures, where the separate contacting of the single quantum wires is realized as in a charge coupled device or a Flash-RAM.

8. Power transistor according to patent claims 1-5 or solar cell according to claim 6, characterized in
that source and drain electrodes consist of an ideally conducting layer
where this said layer consists of crystalline metals at room temperature or moderately lowered temperatures or consists of superconductors at low temperatures or consists of a 2DEG (7a,7b) at room temperature,
where by quantum mechanical phase shift effects of the electronic wave functions in the quantum wires the sensitivity and efficiency of the transistor gain and the solar cell yield is enhanced,
which also represents a model system for a 1-dimensional-direction parallel to the quantum wires—pseudo superconductor at room temperature or slightly lowered temperatures in form of a quantum interference device coupling 10¹⁰-10¹²/cm² parallel quantum wires in the quantum wire array.

9. Quantum field effect transistor according to patent claims 1
characterized in that in this operational mode
the source drain current only through one or a few geometrically and electrically parallel connected quantum wires of the quantum wire array is separately detected at room temperature or moderately lowered temperatures,
where the quantum field effect transistor is a quantum mechanical memory cell and can be switched in current steps I_{sd},
where the source drain current through the said quantum wires or the few parallel connected quantum wires carries secondary stored information,
where an external magnetic or electric or electro-acoustic field or radiation field gates the quantum field effect transistor and controls or modulates the current I_{sd} through the said quantum wires in several steps or continuously,
where a ferromagnetic and or ferroelectric and or antiferroelectric layer (6) is deposited above the source and or drain terminations of the quantum wires, which carries primary stored information by means of which layer (6) the local field stored there in a non-volatile manner controls or modulates in steps the current I_{sd} through the one or few quantum wires directly underneath,
where this ferromagnetic or ferroelectric or antiferroelectric layer (6) is locally magnetized or polarized by a magnetic or electrically charged probe tip (4b) of a scanning probe microscope,
where this ferromagnetic layer consists of Fe or Co or Ni or nanoparticles of such materials,
where this ferroelectric or antiferroelectric layer consists of polarizable nanoparticles,
where the source drain currents I_{sd} through the single quantum wires or groups of a few quantum wires connected in parallel can be read out separately either by a circuitry as in a Flash-RAM or by means of one or many scanning probe tips stationary or mounted to a rotating HDD-read-write head,
whereby source and drain electrodes (3,5) may be ideal electric conductors as well, such as 2-DEGs at room temperature (7a,7b) or superconductors at low temperatures or thin crystalline metal or semiconductor at room temperature or moderately lowered temperatures.

10. A measurement device used in fabricating the device according to claim 1 is characterized in that
it consists of a combined scanning tunneling and scanning force microscope,
where an electrically conductive probe tip at the end of a cantilever spring connected to a voltage source U_{sd} is initially raster-scanned across the 2-dimensional vertical quantum wires' array initially for detecting the single quantum wires' terminations, after which the raster scan is stopped with the tip positioned on top of one quantum wire termination and then the I_{sd}-U_{sd} characteristics of this quantum wire is measured across a protective resistor (8),
where the protective resistor is at least 25.8 kΩ or higher depending on the tiny capacitance of the single quantum wire of the quantum wire array and on the desired sharpness of the quantum conductance peaks,
where the probe tip carries a quantum dot in tunneling contact with the upper termination of the quantum wire defined as source contact,
where the lower terminations of the quantum wires which comprises the entity of drain contacts are connected to earth ground via a further protective resistor and an I-V converter.
